(19) United States
(12) Patent Application Publication
(10) Pub. No.: US 2026/0120745 A1
(43) Pub. Date: Apr. 30, 2026

(54) CONTROL CIRCUIT AND MEMORY

(71) Applicant: CXMT Corporation, Hefei City (CN)

(72) Inventor: Enpeng GAO, Hefei City (CN)

(73) Assignee: CXMT Corporation, Hefei City (CN)

(21) Appl. No.: 19/430,292

(22) Filed: Dec. 23, 2025

Related U.S. Application Data
(63) Continuation of application No. PCT/CN2024/102461, filed on Jun. 28, 2024.

(30) Foreign Application Priority Data
Jul. 3, 2023 (CN) 202310815315.0

(51) Int. Cl. G11C 11/406; G11C 11/408

(52) U.S. Cl. CPC G11C 11/40618; G11C 11/4082; G11C 11/4087

(57) ABSTRACT

A control circuit includes: a command decoding circuit, performing command decoding processing on a first pulse of a chip select signal and a command address signal based on a first clock signal to obtain a first command signal; an address decoding circuit, performing row address decoding processing on a second pulse of the chip select signal and the command address signal based on the first command signal and the first clock signal to obtain n second command signals; and a logic processing circuit, configured to perform logic processing based on the n second command signals to obtain n segment activation signals. A memory array includes m memory banks, each of the memory banks includes n segments, and both m and n are positive integers. Each of the segment activation signals is configured to indicate whether a segment corresponding to at least one of the m memory banks has been activated.

### CROSS-REFERENCE TO RELATED APPLICATIONS

This application is a continuation of International Patent Application No. PCT/CN2024/102461, filed on Jun. 28, 2024, which claims priority to Chinese Patent Application No. 202310815315.0, filed on Jul. 3, 2023. The disclosures of the above-referenced applications are hereby incorporated by reference in their entirety.

### TECHNICAL FIELD

The present disclosure relates to the field of semiconductor technologies, and in particular, to a control circuit and a memory.

### BACKGROUND

With the continuous development of semiconductor technologies, increasingly high requirements are put forward for a data transmission speed in the manufacturing and use of devices such as computers. To achieve faster data transmission speeds, a series of devices such as memories capable of transmitting data at a double data rate (Double Data Rate, DDR) have emerged.

A dynamic random access memory (Dynamic Random Access Memory, DRAM) is utilized as an example, and the DRAM can store data. To maintain integrity of data, the DRAM is periodically refreshed. As the density and speed of the DRAM increase, a refresh operation has an increasingly large impact on the overall performance and power consumption of the DRAM.

### SUMMARY

The present disclosure provides a control circuit and a memory, to achieve an objective of power saving.

According to a first aspect, an embodiment of the present disclosure provides a control circuit. The control circuit includes a command decoding circuit, an address decoding circuit, and a logic processing circuit. The command decoding circuit is connected to the address decoding circuit, and the address decoding circuit is further connected to the logic processing circuit.

The command decoding circuit is configured to receive a command address signal, a chip select signal, and a first clock signal, and perform command decoding processing on a first pulse of the chip select signal and the command address signal based on the first clock signal to obtain a first command signal. The first command signal is configured to indicate whether to perform an activation operation on m memory banks in a memory array. m is a positive integer.

The address decoding circuit is configured to receive the first command signal, the first clock signal, the chip select signal, and the command address signal, and perform row address decoding processing on a second pulse of the chip select signal and the command address signal based on the first command signal and the first clock signal to obtain n second command signals. Each of the second command signals is configured to indicate whether to perform an activation operation on a specific segment in each of the m memory banks. n is a positive integer.

The logic processing circuit is configured to receive the n second command signals, and perform logic processing based on the n second command signals to obtain n segment activation signals. Each of the segment activation signals is configured to indicate whether a segment corresponding to at least one of the m memory banks has been activated. The memory array includes the m memory banks, each of the memory banks includes n segments, and the n segments correspond to the n segment activation signals.

In some embodiments, the first command signal includes m first command sub-signals, and the m first command sub-signals correspond to the m memory banks. If the first command sub-signals are in a first level state, it is determined to perform an activation operation on the memory banks corresponding to the first command sub-signals; or if the first command sub-signals are in a second level state, it is determined to skip performing an activation operation on the memory banks corresponding to the first command sub-signals.

In some embodiments, the address decoding circuit is further configured to perform row address decoding processing on the second pulse of the chip select signal and the command address signal based on the first command signal and the first clock signal to obtain n third command signals. The second command signals and the third command signals are inversely related to each other. The logic processing circuit is configured to receive the n second command signals and the n third command signals, and perform logic processing based on the n second command signals and the n third command signals to obtain the n segment activation signals.

In some embodiments, the logic processing circuit includes n segment processing sub-circuits. An ith segment processing sub-circuit is configured to receive an ith second command signal and an ith third command signal, and perform logic processing based on the ith second command signal and the ith third command signal to obtain an ith segment activation signal. The ith segment activation signal is configured to indicate whether an ith segment corresponding to at least one of the m memory banks has been activated. i is an integer greater than or equal to 0 and less than n.

In some embodiments, each of the second command signals includes m second command sub-signals, and each of the third command signals includes m third command sub-signals. The second command sub-signals and the third command sub-signals are inversely related to each other, both a kth second command sub-signal in the second command signal and a kth third command sub-signal in the third command signal correspond to a kth memory bank, and k is an integer greater than or equal to 0 and less than m.

In some embodiments, the ith segment processing sub-circuit includes m logic sub-circuits and a control sub-circuit. A jth logic sub-circuit is configured to receive a ground signal, a jth second command sub-signal, and a jth third command sub-signal. An output terminal of the jth logic sub-circuit is configured to output a jth first intermediate signal, and j is an integer greater than or equal to 0 and less than m. A first input terminal of the control sub-circuit is connected to output terminals of the m logic sub-circuits. A second input terminal of the control sub-circuit is configured to receive a power-up signal. An output terminal of the control sub-circuit is configured to output the ith segment activation signal. The chip select signal is a signal representing that a target chip is selected, and the power-up signal represents that all power supplies of the target chip are started.

In some embodiments, the jth logic sub-circuit includes a jth latch module and a jth gated buffer module. An output terminal of the jth latch module is connected to an input terminal of the jth gated buffer module, and a control terminal of the jth gated buffer module is configured to receive the jth third command sub-signal. The jth latch module is configured to receive the ground signal and the jth second command sub-signal, and control a latch status of the jth latch module based on the jth second command sub-signal to generate a jth second intermediate signal. The jth gated buffer module is configured to receive the jth second intermediate signal and the jth third command sub-signal, and control a conduction status of the jth gated buffer module based on the jth third command sub-signal to generate the jth first intermediate signal.

In some embodiments, the jth logic sub-circuit is configured to: when the jth second command sub-signal is in the first level state and the jth third command sub-signal is in the second level state, determine that the jth second intermediate signal is in the second level state and the jth gated buffer module is in an on state, so that the jth first intermediate signal is in the second level state.

In some embodiments, the jth logic sub-circuit is configured to: when the jth second command sub-signal is in the second level state and the jth third command sub-signal is in the first level state, determine that the jth gated buffer module is in an off state, so that an output of the jth gated buffer module is in a high-impedance state.

In some embodiments, the control sub-circuit includes a first OR gate, a first buffer, and an mth gated buffer module. A first input terminal of the first OR gate is separately connected to the output terminals of the m logic sub-circuits and an output terminal of the mth gated buffer module. A second input terminal of the first OR gate is configured to receive the power-up signal. An output terminal of the first OR gate is separately connected to an input terminal of the mth gated buffer module and an input terminal of the first buffer. A control terminal of the mth gated buffer module is configured to receive the power-up signal. An output terminal of the first buffer is configured to output the ith segment activation signal.

In some embodiments, the control circuit further includes a mode register and an output circuit. The mode register is configured to output n initial segment mask signals. Each of the initial segment mask signals is set by the mode register and is configured to indicate whether refresh masking is performed for the specific segment in each of the m memory banks. The output circuit is configured to receive the n segment activation signals and the n initial segment mask signals, and perform OR logic processing on the n segment activation signals and the n initial segment mask signals to generate n target segment mask signals.

If an ith target segment mask signal is in the first level state, a refresh operation is masked for the ith segment corresponding to at least one of the m memory banks when the refresh operation is performed; or if an ith target segment mask signal is in the second level state, a refresh operation is not masked for the ith segment corresponding to each of the m memory banks when the refresh operation is performed.

In some embodiments, the first level state is a high level, and the second level state is a low level.

In some embodiments, the output circuit includes n second OR gates. A first input terminal of a pth second OR gate is configured to receive a pth segment activation signal, and a second input terminal of the pth second OR gate is configured to receive a pth initial segment mask signal. An output terminal of the pth second OR gate is configured to output a pth target segment mask signal. p is an integer greater than or equal to 0 and less than n.

In some embodiments, the output circuit includes n second OR gates and n second buffers. An input terminal of a pth second buffer is connected to an output terminal of a pth second OR gate. The pth second OR gate is configured to receive a pth segment activation signal and a pth initial segment mask signal, and perform an OR logic operation on the pth segment activation signal and the pth initial segment mask signal to obtain a pth intermediate segment mask signal. The pth second buffer is configured to perform drive enhancement processing on the pth intermediate segment mask signal to obtain a pth target segment mask signal. p is an integer greater than 0 and less than or equal to n.

According to a second aspect, an embodiment of the present disclosure provides a memory. The memory includes at least the control circuit according to the first aspect.

Embodiments of the present disclosure provide a control circuit and a memory. The control circuit includes the command decoding circuit, the address decoding circuit, and the logic processing circuit. The command decoding circuit is configured to perform command decoding processing on the first pulse of the chip select signal and the command address signal based on the first clock signal to obtain the first command signal. The first command signal is configured to indicate whether to perform an activation operation on the m memory banks in the memory array. m is a positive integer. The address decoding circuit is configured to perform row address decoding processing on the second pulse of the chip select signal and the command address signal based on the first command signal and the first clock signal to obtain the n second command signals and the n third command signals. The second command signals and the third command signals are inversely related to each other. Each of the second command signals is configured to indicate whether to perform an activation operation on the specific segment in each of the m memory banks. n is a positive integer. The logic processing circuit is configured to perform logic processing based on the n second command signals and the n third command signals to obtain the n segment activation signals. The memory array includes the m memory banks, and each of the memory banks includes the n segments. The n segments correspond to the n segment activation signals. Each of the segment activation signals is configured to indicate whether the segment corresponding to at least one of the m memory banks has been activated. In this way, if it can be determined based on the segment activation signal that a segment corresponding to each of some memory banks has been activated, it means that the segment corresponding to each of these memory banks has already been accessed. Then, the segment needs to be periodically refreshed in a refresh operation stage. Otherwise, if it can be determined based on the segment activation signal that a segment corresponding to each of some memory banks has not been activated, it means that the segment corresponding to each of these memory banks has not been accessed. Then, refresh masking may be performed for the segment in a refresh operation stage. In this way, integrity of data in the memory banks can be maintained, and power consumption can be further reduced, thereby achieving an objective of power saving, and finally improving performance of the memory.

### BRIEF DESCRIPTION OF DRAWINGS

FIG. 1 is a schematic diagram 1 of a compositional structure of a control circuit according to an embodiment of the present disclosure;

FIG. 2 is a schematic diagram of a compositional structure of a logic processing circuit according to an embodiment of the present disclosure;

FIG. 3 is a schematic diagram of a compositional structure of a segment processing sub-circuit according to an embodiment of the present disclosure;

FIG. 4 is a schematic diagram of a compositional structure of a logic sub-circuit according to an embodiment of the present disclosure;

FIG. 5 is a schematic diagram of a compositional structure of a control sub-circuit according to an embodiment of the present disclosure;

FIG. 6 is a schematic diagram 2 of a compositional structure of a control circuit according to an embodiment of the present disclosure;

FIG. 7 is a schematic diagram 1 of a compositional structure of an output circuit according to an embodiment of the present disclosure;

FIG. 8 is a schematic diagram 2 of a compositional structure of an output circuit according to an embodiment of the present disclosure;

FIG. 9 is a schematic diagram of an architecture of a memory according to an embodiment of the present disclosure;

FIG. 10 is a schematic diagram 1 of a refined structure of a local part of a control circuit according to an embodiment of the present disclosure;

FIG. 11 is a schematic diagram 2 of a refined structure of a local part of a control circuit according to an embodiment of the present disclosure;

FIG. 12 is a schematic diagram of signal timing according to an embodiment of the present disclosure; and

FIG. 13 is a schematic diagram of a compositional structure of a memory according to an embodiment of the present disclosure.

### DESCRIPTION OF EMBODIMENTS

The technical solutions in the embodiments of the present disclosure are clearly and completely described below with reference to the accompanying drawings in the embodiments of the present disclosure. It can be understood that specific embodiments described herein are merely intended to explain the related application, but are not intended to limit this application. In addition, it should be further noted that for ease of description, only parts related to the related application are shown in the accompanying drawings.

Unless otherwise defined, all technical and scientific terms employed in this specification have meanings the same as those commonly understood by a person skilled in the technical field of the present disclosure. The terms employed in this specification are merely intended to describe the embodiments of the present disclosure, but are not intended to limit the present disclosure.

“Some embodiments” describing a subset of all possible embodiments is involved in the following descriptions. However, it may be understood that “some embodiments” may be the same subset or different subsets of all the possible embodiments, and may be combined with each other when there is no conflict.

It should be noted that the term “first/second/third” in the embodiments of the present disclosure is merely intended to distinguish between similar objects, and does not represent specific sorting for the objects. It may be understood that “first/second/third” may be interchanged for a specific sequence or order if allowed, so that the embodiments of the present disclosure described herein can be implemented in a sequence other than those shown or described herein.

It should be further noted that a high level and a low level related to a signal in the embodiments of the present disclosure refer to logic levels of the signal. There is a difference between a signal having a high level and the signal having a low level. For example, a high level may correspond to a signal having a first voltage, and a low level may correspond to a signal having a second voltage. In some embodiments, the first voltage is greater than the second voltage. In addition, logic levels of a signal may be different or opposite to the described logic levels. For example, a signal described as having a “high” logic level may alternatively have a “low” logic level, and a signal described as having a “low” logic level may alternatively have a “high” logic level.

It can be understood that a dynamic random access memory (Dynamic Random Access Memory, DRAM) needs to maintain data in a memory array through a refresh operation. Each refresh operation enables at least one memory bank (Bank) in the memory array, and the refresh operation is performed on the enabled memory bank. However, as the density and speed of the DRAM increase, the refresh operation has an increasingly large impact on the overall performance and power consumption of the DRAM.

In the embodiments of the present disclosure, each memory bank in the memory array may be divided into multiple segments (Segment/Section). Storage density corresponds to a quantity of divided segments. For example, if the storage density is 8 GB, eight segments may be obtained through division. If the storage density is 6 GB, six segments may be obtained through division. If the storage density is 4 GB, four segments may be obtained through division. However, this is not specifically limited herein.

In some embodiments, it is assumed that the memory array includes eight memory banks, which are specifically Bank0, Bank1, Bank2, . . . , and Bank7. Whether or not a self-refresh operation is being performed, segments corresponding to each of the eight memory banks may be independently configured. A mode register 23 (Mode Register23, MR23) is utilized as an example. The mode register MR 23 may be accessed with a mode register write (Mode Register Write, MRW) command, and is configured to indicate a masking status of each segment. Table 1 shows an application example of segment masking.

TABLE 1

| | Segment | | | | | | | | |
|---|---|---|---|---|---|---|---|---|---|
| | mask | | | | | | | | |
| | (MR23) | Bank0 | Bank1 | Bank2 | Bank3 | Bank4 | Bank5 | Bank6 | Bank7 |
| Segment 0 | 0 | | | | | | | | |
| Segment 1 | 0 | | | | | | | | |
| Segment 2 | 1 | M | M | M | M | M | M | M | M |
| Segment 3 | 0 | | | | | | | | |
| Segment 4 | 0 | | | | | | | | |
| Segment 5 | 0 | | | | | | | | |
| Segment 6 | 0 | | | | | | | | |
| Segment 7 | 1 | M | M | M | M | M | M | M | M |

Each memory bank herein may have a maximum of eight segments, and the eight segments specifically include a segment 0 (Segment 0), a segment 1 (Segment 1), a segment 2 (Segment 2), . . . , and a segment 7 (Segment 7). The segment mask (Segment Mask) is utilized to control whether to perform a refresh operation on a specific segment of the entire memory array. When the specific segment is masked with the MRW command, a self-refresh operation for the entire segment is prevented, and it cannot be ensured that data of the segment is retained in a self-refresh mode. It can be learned from Table 1 that segment masks corresponding to the segment 2 and the segment 7 are 1. In this case, in each of Bank0 to Bank7, the refresh operation for both the segment 2 and the segment 7 is masked (Masked, M).

In actual application, for whether refresh masking is to be performed for a segment of a memory bank, if a specific segment has not been accessed (that is, a read/write operation has not been performed), data in the segment is not of important value. In this case, the refresh operation may not be performed on the segment, that is, refresh masking may be performed for the segment.

Based on this, an embodiment of the present disclosure provides a control circuit. The control circuit includes a command decoding circuit, an address decoding circuit, and a logic processing circuit. A memory array includes m memory banks, and each of the memory banks includes n segments. The n segments correspond to n segment activation signals. Each of the segment activation signals is configured to indicate whether a segment corresponding to at least one of the m memory banks has been activated. In this way, if it can be determined based on the segment activation signal that a segment corresponding to each of some memory banks has been activated, it means that the segment corresponding to each of these memory banks has already been accessed. Then, the segment needs to be periodically refreshed in a refresh operation stage. Otherwise, if it can be determined based on the segment activation signal that a segment corresponding to each of some memory banks has not been activated, it means that the segment corresponding to each of these memory banks has not been accessed. Then, refresh masking may be performed for the segment in a refresh operation stage. In this way, integrity of data in the memory banks can be maintained, and power consumption can be further reduced, thereby achieving an objective of power saving, and finally improving performance of the memory.

The following describes the embodiments of the present disclosure in detail with reference to the accompanying drawings.

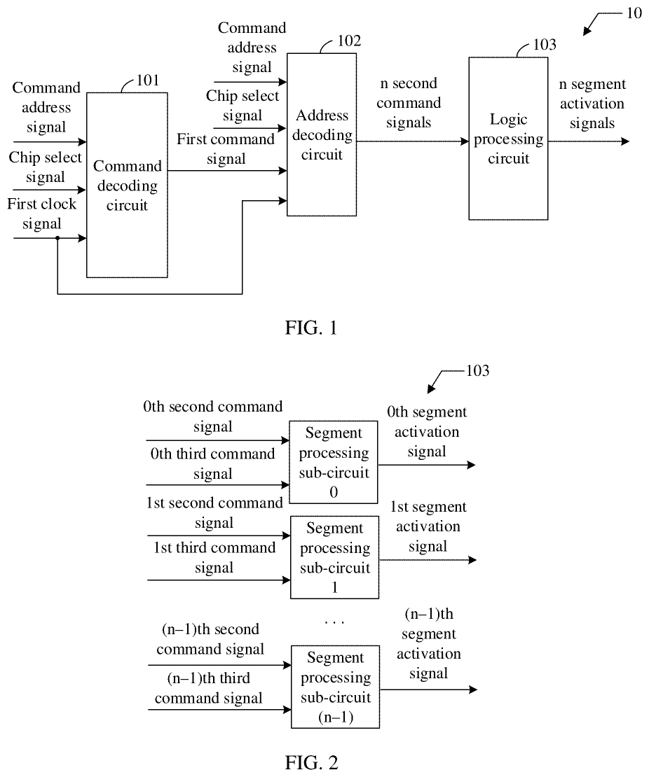

In an embodiment of the present disclosure, refer to FIG. 1, which is a schematic diagram of a compositional structure of a control circuit according to an embodiment of the present disclosure. As shown in FIG. 1, the control circuit 10 may include a command decoding circuit 101, an address decoding circuit 102, and a logic processing circuit 103. The command decoding circuit 101 is connected to the address decoding circuit 102, and the address decoding circuit 102 is further connected to the logic processing circuit 103.

The command decoding circuit 101 is configured to receive a command address signal, a chip select signal, and a first clock signal, and perform command decoding processing on a first pulse of the chip select signal and the command address signal based on the first clock signal to obtain a first command signal. The first command signal is configured to indicate whether to perform an activation operation on m memory banks in a memory array. m is a positive integer.

The address decoding circuit 102 is configured to receive the first command signal, the first clock signal, the chip select signal, and the command address signal, and perform row address decoding processing on a second pulse of the chip select signal and the command address signal based on the first command signal and the first clock signal to obtain n second command signals. Each of the second command signals is configured to indicate whether to perform an activation operation on a specific segment in each of the m memory banks. n is a positive integer.

The logic processing circuit 103 is configured to receive the n second command signals, and perform logic processing based on the n second command signals to obtain n segment activation signals. Each of the segment activation signals is configured to indicate whether a segment corresponding to at least one of the m memory banks has been activated.

It should be noted that the control circuit 10 in this embodiment of the present disclosure is applied to a memory, to resolve a problem that a refresh operation has a great impact on the overall performance and power consumption of the memory. Specifically, in this embodiment of the present disclosure, the control circuit 10 may be a refresh control circuit that can reduce power consumption in a refresh operation stage, thereby achieving an objective of power saving.

It should be further noted that in this embodiment of the present disclosure, the memory array may include the m memory banks, each of the memory banks may include n segments, and the n segments correspond to the n segment activation signals. That is, an ith segment activation signal is configured to indicate whether an ith segment in at least one of all the memory banks has been activated. i is an integer greater than or equal to 0 and less than n.

For example, it is assumed that m is equal to 16, and n is equal to 8. Then, a total of 16 memory banks are included herein, which are specifically Bank0, Bank1, Bank2, . . . , and Bank15. Each of the memory banks may include eight segments, which are specifically Segment 0, Segment 1, Segment 2, . . . , and Segment 7. Correspondingly, there are also eight segment activation signals generated herein. The ith segment activation signal may be represented by ActSegMsk<i>. Therefore, the segment activation signals corresponding to the eight segments are successively: ActSegMsk<0>, ActSegMsk<1>, ActSegMsk<2>, . . . , and ActSegMsk<7>. If the signal ActSegMsk<i> herein is in a first level state, it indicates that the ith segment in each of the memory banks in the memory array has not been activated. If the signal ActSegMsk<i> is in a second level state, it indicates that the ith segment in at least one memory bank in the memory array has been activated.

It should be further noted that in this embodiment of the present disclosure, the segment activation signal can determine whether a segment corresponding to each of some memory banks has been activated. Specifically, if the segment corresponding to each of these memory banks has been activated, it means that the segment has already been accessed, and data stored in the segment is valid. In this case, to ensure integrity of the data, refresh masking cannot be performed for the segment in a refresh operation stage. If the segment corresponding to each of these memory banks has not been activated, it means that the segment has not been accessed, and data stored in the segment is not important. In this case, refresh masking may be performed for the segment in a refresh operation stage. Therefore, a refresh current and refreshing power consumption can be reduced, and the objective of power saving can be achieved.

In some embodiments, the first command signal may include m first command sub-signals, and the m first command sub-signals correspond to the m memory banks.

If the first command sub-signals are in a first level state, it is determined to perform an activation operation on the memory banks corresponding to the first command sub-signals.

If the first command sub-signals are in a second level state, it is determined to skip performing an activation operation on the memory banks corresponding to the first command sub-signals.

It should be noted that in this embodiment of the present disclosure, the first command signal may be configured to indicate which memory bank is specifically activated, and the first command signal may be represented by ActBnk1. In addition, the first command signal is not a single signal but a group of signals. Herein, a quantity of first command sub-signals in the first command signal is the same as a quantity of memory banks, that is, each of the memory banks respectively corresponds to one first command sub-signal. An lth first command sub-signal corresponding to an lth memory bank may be represented by ActBnk1<l>, and/is an integer greater than or equal to 0 and less than m.

It should be further noted that in this embodiment of the present disclosure, the first level state may be a high level, for example, logic 1; and the second level state may be a low level, for example, logic 0. This is not specifically limited.

That is, in this embodiment of the present disclosure, if the lth first command sub-signal is at the high level, it can be determined to perform an activation operation on the lth memory bank. If the lth first command sub-signal is at the low level, it can be determined to skip performing an activation operation on the lth memory bank.

It can be understood that in this embodiment of the present disclosure, the command address signal may be represented by CA<6:0>. It should be noted that the command address signal herein is not a single signal but a group of signals, which are specifically CA0, CA1, CA2, CA3, CA4, CA5, and CA6. The chip select signal may be represented by CS, and the chip select signal is a signal representing that a target chip is selected. In this way, the first command signal may be obtained through command decoding processing performed by the command decoding circuit 101 on the first pulse of the chip select signal and the command address signal based on the first clock signal.

In some embodiments, the address decoding circuit 102 is further configured to perform row address decoding processing on the second pulse of the chip select signal and the command address signal based on the first command signal and the first clock signal to obtain n third command signals. The second command signals and the third command signals are inversely related to each other.

The logic processing circuit 103 is configured to receive the n second command signals and the n third command signals, and perform logic processing based on the n second command signals and the n third command signals to obtain the n segment activation signals.

It should be noted that in this embodiment of the present disclosure, the third command signals are inverted signals of the second command signals. That is, the third command signals may be obtained through inversion processing for the second command signals. Therefore, the third command signals may be generated in the address decoding circuit 102, or the third command signals may be generated in the logic processing circuit 103. This is not specifically limited herein.

In some embodiments, for the logic processing circuit 103, refer to FIG. 2. The logic processing circuit 103 may include n segment processing sub-circuits.

An ith segment processing sub-circuit is configured to receive an ith second command signal and an ith third command signal, and perform logic processing based on the ith second command signal and the ith third command signal to obtain an ith segment activation signal.

The ith segment activation signal is configured to indicate whether an ith segment corresponding to at least one of the m memory banks has been activated. i is an integer greater than or equal to 0 and less than n.

It should be noted that in this embodiment of the present disclosure, the ith segment processing sub-circuit may be represented by a segment processing sub-circuit i. In this way, in FIG. 2, the n segment processing sub-circuits may include: a segment processing sub-circuit 0, a segment processing sub-circuit 1, . . . , and a segment processing sub-circuit n−1. Each of the segment processing sub-circuits may be configured to process a specific segment corresponding to each of the m memory banks. Specifically, each of the segment activation signals may be configured to indicate whether a specific segment corresponding to at least one of the m memory banks has been activated.

It should be further noted that in this embodiment of the present disclosure, the ith second command signal is not a single signal but a group of signals, and the ith third command signal is not a single signal but a group of signals. In some embodiments, each of the second command signals may include m second command sub-signals and each of the third command signals may include m third command sub-signals.

The second command sub-signals and the third command sub-signals are inversely related to each other, both a kth second command sub-signal in the second command signal and a kth third command sub-signal in the third command signal correspond to a kth memory bank, and k is an integer greater than or equal to 0 and less than m.

It can be understood that in this embodiment of the present disclosure, the second command signals and the third command signals that are generated by the address decoding circuit 102 are inversely related to each other. For a qth segment, a qth second command signal may be represented by SegqAct<m−1:0>, a qth third command signal may be represented by SegqActN<m−1:0>, “N” represents “inverted”, and q is an integer greater than or equal to 0 and less than n.

For example, it is assumed that a value of m is 16. Then, the qth second command signal may include multiple second command sub-signals such as SegqAct<0>, SegqAct<1>, . . . , and SegqAct<15>, and the qth third command signal may include multiple third command sub-signals such as SegqActN<0>, SegqActN<1>, . . . , and SegqActN<15>. In this way, for Bank0, SegqAct<0> and SegqActN<0> correspond to Bank0; for Bank1, SegqAct<1> and SegqActN<1> correspond to Bank1; . . . ; and for Bank15, SegqAct<15> and SegqActN<15> correspond to Bank15.

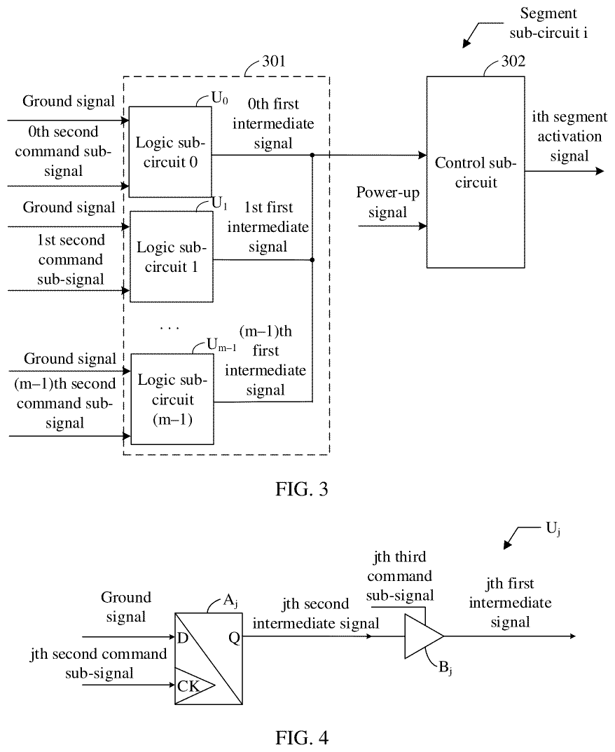

In some embodiments, for the segment processing sub-circuit i, refer to FIG. 3. The ith segment processing sub-circuit may include m logic sub-circuits 301 and a control sub-circuit 302.

In the m logic sub-circuits 301, a jth logic sub-circuit is configured to receive a ground signal, a jth second command sub-signal, and a jth third command sub-signal. An output terminal of the jth logic sub-circuit is configured to output a jth first intermediate signal, and j is an integer greater than or equal to 0 and less than m.

A first input terminal of the control sub-circuit 302 is connected to output terminals of the m logic sub-circuits 302, a second input terminal of the control sub-circuit 302 is configured to receive a power-up signal, and an output terminal of the control sub-circuit 302 is configured to output the ith segment activation signal.

It should be noted that in this embodiment of the present disclosure, the chip select signal is a signal representing that a target chip is selected, and the power-up signal represents that all power supplies of the target chip are started.

It should be further noted that in this embodiment of the present disclosure, in the m logic sub-circuits 301, the jth logic sub-circuit may be represented by Uⱼ. Therefore, in FIG. 3, there are m logic sub-circuits in total, such as a 0th logic sub-circuit (also referred to as a “logic sub-circuit 0”) U₀, a 1st logic sub-circuit (also referred to as a “logic sub-circuit 1”) U₁, . . . , and an (m−1)th logic sub-circuit (also referred to as a “logic sub-circuit m−1”) Uₘ₋₁.

In some embodiments, for the jth logic sub-circuit Uⱼ, refer to FIG. 4. The jth logic sub-circuit Uⱼ may include a jth latch module Aⱼ and a jth gated buffer module Bⱼ. An output terminal of the jth latch module Aⱼ is connected to an input terminal of the jth gated buffer module Bⱼ, and a control terminal of the jth gated buffer module Bⱼ is configured to receive the jth third command sub-signal.

The jth latch module Aⱼ is configured to receive the ground signal and the jth second command sub-signal, and control a latch status of the jth latch module Aⱼ based on the jth second command sub-signal to generate a jth second intermediate signal.

The jth gated buffer module Bⱼ is configured to receive the jth second intermediate signal and the jth third command sub-signal, and control a conduction status of the jth gated buffer module Bⱼ based on the jth third command sub-signal to generate the jth first intermediate signal.

It should be noted that in this embodiment of the present disclosure, each latch module may include a clock terminal (CK), an input terminal (D), and an output terminal (Q). The latch module herein is different from a D-type flip-flop. The D-type flip-flop is clock edge-triggered, and the latch module controls conduction based on a level state. For example, the jth latch module Aⱼ is utilized as an example. The ground signal connected to the D terminal of the jth latch module Aⱼ is transmitted to the Q terminal of the jth latch module Aⱼ when the jth second command sub-signal is in the high level state, so that an output of the Q terminal is in the low level state. In addition, an initial value of the Q terminal of each latch module is the high level state.

It should be further noted that in this embodiment of the present disclosure, each gated buffer module may include an input terminal, an output terminal, and a control terminal. The control terminal of the gated buffer module is configured to receive a control signal. The gated buffer module may be turned on when the control signal is in the low level state, so that a signal received through the input terminal of the gated buffer module is transmitted to the output terminal of the gated buffer module.

It should be further noted that in this embodiment of the present disclosure, each of the logic sub-circuits includes the gated buffer module. Because the gated buffer module has one more control signal than a common buffer, data is transmitted when the control signal is at the low level. When the first input terminal of the control sub-circuit 302 is connected to the output terminals of the m logic sub-circuits 302, multiple first intermediate signals are simultaneously connected to an input of the control sub-circuit 302, resulting in a signal conflict. However, this case can be avoided through the added gated buffer module. Because a gated buffer module corresponding to a segment of a memory bank that has not been accessed is not turned on, these first intermediate signals have no capability of driving the input of the control sub-circuit 302 connected thereto.

It can be further understood that in this embodiment of the present disclosure, because the gated buffer module is affected by the control terminal thereof, the gated buffer module may include two states: on and off. Consequently, outputs of the gated buffer module are different. The following describes in detail two output cases of the jth gated buffer module Bⱼ.

In a possible implementation, the jth logic sub-circuit Uⱼ is configured to: when the jth second command sub-signal is in the first level state and the jth third command sub-signal is in the second level state, determine that the jth second intermediate signal is in the second level state and the jth gated buffer module Bⱼ is in an on state, so that the jth first intermediate signal is in the second level state.

In another possible implementation, the jth logic sub-circuit Uⱼ is configured to: when the jth second command sub-signal is in the second level state and the jth third command sub-signal is in the first level state, determine that the jth gated buffer module Bⱼ is in an off state, so that an output of the jth gated buffer module Bⱼ is in a high-impedance state.

It should be noted that in this embodiment of the present disclosure, the first level state may be a high level, for example, logic 1; and the second level state may be a low level, for example, logic 0. This is not specifically limited.

It should be further noted that in this embodiment of the present disclosure, the jth logic sub-circuit Uⱼ is utilized as an example. If the jth second command sub-signal is at the high level, the latch module Aⱼ may transmit the logic 0 at the input terminal thereof to the output terminal of the latch module Aⱼ, that is, the jth second intermediate signal is at the low level. Because the jth third command sub-signal is at the low level, the gated buffer module Bⱼ is in the on state, that is, the jth first intermediate signal is at the low level. Alternatively, if the jth second command sub-signal is at the low level, the latch module Aⱼ cannot transmit the logic 0 at the input terminal thereof to the output terminal of the latch module Aⱼ, that is, the jth second intermediate signal remains in an initial state (in this case, at the high level). Because the jth third command sub-signal is at the high level, the gated buffer module Bⱼ is not turned on, that is, the output of the gated buffer module Bⱼ is in the high-impedance state.

For example, it is assumed that a value of m is 16. A 0th segment is utilized as an example. 16 second command sub-signals may include Seg0Act<0>, Seg0Act<1>, . . . , and Seg0Act<15>, and 16 third command sub-signals may include Seg0ActN<0>, Seg0ActN<1>, . . . , and Seg0ActN<15>. If Seg0Act<0> is at the low level, and Seg0ActN<0> is at the high level, in this case, the 0th segment representing a 0th memory bank has not been accessed, and neither a latch module A₀ nor a gated buffer module B₀ transmits data. If a pulse exists in Seg0Act<0>, that is, Seg0Act<0> is at the high level, in this case, the 0th segment representing a 0th memory bank has been accessed, a latch module A₀ may output the logic 0, and a gated buffer module B₀ is also turned on under the control of Seg0ActN<0> being at the low level, and transmits the logic 0 to the first input terminal of the control sub-circuit 302. In addition, for a 0th segment of an rth memory bank that has not been accessed, Seg0Act<r> is at the low level, and Seg0ActN<r> is at the high level. In this case, the gated buffer module is not turned on, and the output is in the high-impedance state. In this case, the gated buffer module in the off state has no capability of driving the first input terminal of the control sub-circuit 302, thereby avoiding a signal conflict occurring when the 16 gated buffer modules simultaneously drive the first input terminal of the control sub-circuit 302. r=0, 1, 2, . . . , 15.

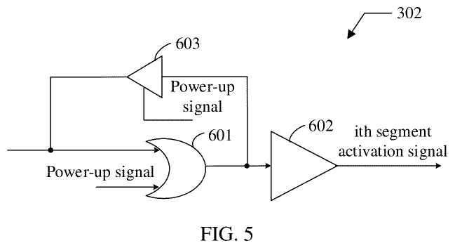

In some embodiments, for the control sub-circuit 302, refer to FIG. 5. The control sub-circuit 302 may include a first OR gate 601, a first buffer 602, and an mth gated buffer module 603.

A first input terminal of the first OR gate 601 is separately connected to the output terminals of the m logic sub-circuits 301 and an output terminal of the mth gated buffer module 603. A second input terminal of the first OR gate 601 is configured to receive the power-up signal. An output terminal of the first OR gate 601 is separately connected to an input terminal of the mth gated buffer module 603 and an input terminal of the first buffer 602. A control terminal of the mth gated buffer module 603 is configured to receive the power-up signal. An output terminal of the first buffer 602 is configured to output the ith segment activation signal.

It should be noted that in this embodiment of the present disclosure, the power-up signal may be represented by PwrUp. The power-up signal represents that all the power supplies of the target chip are started, or initialization of the target chip is completed. For the power-up signal, if the power-up signal is at the high level, it may represent that the target chip is being powered up. If the power-up signal is at the low level, it represents that power-up of the target chip is completed.

It should be further noted that in this embodiment of the present disclosure, before power-up is completed and when power-up is just completed, the ith segment activation signal is at the high level (that is, the logic 1). Specifically, before power-up is completed, the power-up signal in this case is at the high level, an OR logic operation is performed on the power-up signal and signals at the output terminals of the m logic sub-circuits 301 through the first OR gate 601, so that the finally output ith segment activation signal is at the high level. Because power-up is not completed in this case, any segment in the memory banks may not be activated. In addition, when power-up is just completed, because the power-up signal is just flipped to the low level, when no activation operation occurs, the finally output ith segment activation signal in this case is also at the high level.

In short, before power-up is completed and when power-up is just completed, each of all segments (such as the segment 0 to the segment 7) in the memory banks is not activated. Therefore, all the segment activation signals ActSegMsk<7:0> are at the high level.

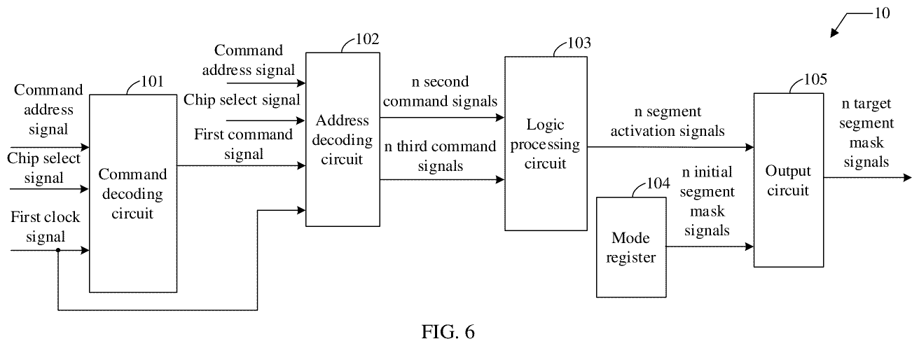

In some embodiments, based on the control circuit 10 shown in FIG. 1, refer to FIG. 6. The control circuit 10 may further include a mode register 104 and an output circuit 105.

The mode register 104 is configured to output n initial segment mask signals. Each of the initial segment mask signals is set by the mode register and is configured to indicate whether refresh masking is performed for the specific segment in each of the m memory banks.

The output circuit 105 is configured to receive the n segment activation signals and the n initial segment mask signals, and perform OR logic processing on the n segment activation signals and the n initial segment mask signals to generate n target segment mask signals.

It should be noted that in this embodiment of the present disclosure, an ith initial segment mask signal may be represented by MRSegMsk<i>, and the mode register 104 may be a mode register MR23. The ith initial segment mask signal is set by the mode register MR23 and is specifically configured to indicate whether a refresh operation is masked for the ith segment. Refer to Table 1 described above. If “the ith segment needs to be masked” is set by the mode register MR23, the refresh operation is masked for the ith segment. In this way, an ith target segment mask signal may be generated through the OR logic processing based on the ith segment activation signal and the ith initial segment mask signal.

In some embodiments, if the ith target segment mask signal is in the first level state, a refresh operation is masked for the ith segment corresponding to at least one of the m memory banks when the refresh operation is performed; or if the ith target segment mask signal is in the second level state, a refresh operation is not masked for the ith segment corresponding to each of the m memory banks when the refresh operation is performed.

It should be noted that in this embodiment of the present disclosure, the first level state may be a high level, for example, logic 1; and the second level state may be a low level, for example, logic 0. This is not specifically limited.

It should be further noted that in this embodiment of the present disclosure, each of the target segment mask signals is configured to indicate whether to mask a refresh operation for a specific segment corresponding to at least one of the m memory banks. Specifically, in a refresh operation stage, if the target segment mask signal is at the high level, the refresh operation may be masked for the specific segment corresponding to at least one of the m memory banks. Otherwise, if the target segment mask signal is at the low level, the refresh operation does not need to be masked for the specific segment corresponding to each of the m memory banks, that is, in this case, the refresh operation needs to be performed for the specific segment corresponding to each of the m memory banks.

For example, the ith segment is utilized as an example. The ith target segment mask signal may be represented by SegMsk<i>. If the signal SegMsk<i> is at the high level, the refresh operation may be masked for the ith segment corresponding to at least one of the m memory banks; or if the signal SegMsk<i> is at the low level, the refresh operation needs to be performed for the ith segment corresponding to each of the m memory banks.

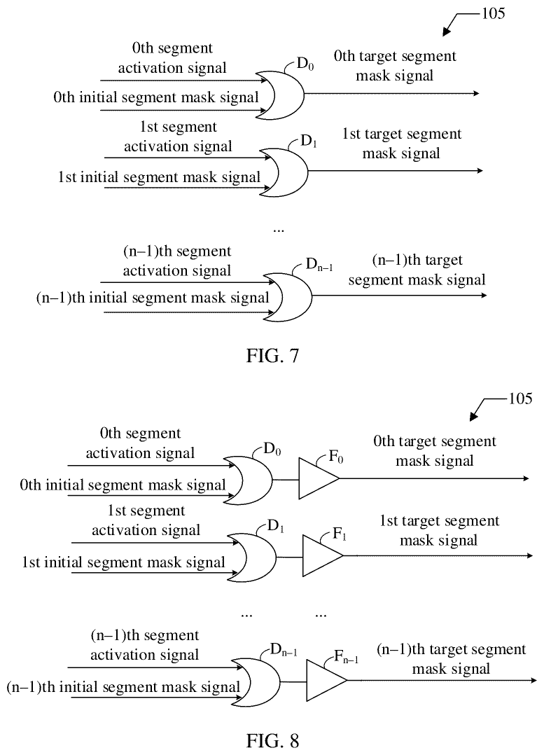

In a possible implementation, refer to FIG. 7. The output circuit 105 may include n second OR gates.

A first input terminal of a pth second OR gate is configured to receive a pth segment activation signal, a second input terminal of the pth second OR gate is configured to receive a pth initial segment mask signal, and an output terminal of the pth second OR gate is configured to output the pth target segment mask signal.

In this embodiment of the present disclosure, p is an integer greater than or equal to 0 and less than n.

It should be further noted that in FIG. 7, the n second OR gates are respectively represented by D₀, D₁, . . . , and Dₙ₋₁. For the pth segment, the first input terminal of the pth second OR gate Dₚ is configured to receive the pth segment activation signal ActSegMsk<p>, the second input terminal of the pth second OR gate Dₚ is configured to receive the pth initial segment mask signal MRSegMsk<p>, and the output terminal of the pth second OR gate Dₚ is configured to output the pth target segment mask signal SegMsk<p>.

In another possible implementation, refer to FIG. 8. The output circuit 105 may include n second OR gates and n second buffers. An input terminal of a pth second buffer is connected to an output terminal of a pth second OR gate.

The pth second OR gate is configured to receive a pth segment activation signal and a pth initial segment mask signal, and perform an OR logic operation on the pth segment activation signal and the pth initial segment mask signal to obtain a pth intermediate segment mask signal.

The pth second buffer is configured to perform drive enhancement processing on the pth intermediate segment mask signal to obtain a pth target segment mask signal.

In this embodiment of the present disclosure, p is an integer greater than or equal to 0 and less than n.

It should be further noted that in FIG. 8, the n second OR gates are respectively represented by D₀, D₁, . . . , and Dₙ₋₁, and the n second buffers are respectively represented by F₀, F₁, . . . , and Fₙ₋₁. For the pth segment, a first input terminal of the pth second OR gate Dₚ is configured to receive the pth segment activation signal ActSegMsk<p>, and a second input terminal of the pth second OR gate Dₚ is configured to receive the pth initial segment mask signal MRSegMsk<p>. The output terminal of the pth second OR gate Dₚ is connected to the input terminal of the pth second buffer Fₚ, and an output terminal of the pth second buffer Fₚ is configured to output the pth target segment mask signal SegMsk<p>.

In short, compared with FIG. 7, the second buffer is added at the output terminal in FIG. 8, thereby implementing a delay function and implementing a function of improving a signal driving capability. Specifically, for the pth target segment mask signal and the pth intermediate segment mask signal, a driving capability of the pth target segment mask signal is stronger than that of the pth intermediate segment mask signal. In addition, it should be noted that if the second buffer is replaced with a gated buffer (that is, an additional control signal is added), a function of controlling transmission may be further implemented based on the control signal.

This embodiment provides a control circuit. In the control circuit, the command decoding circuit is configured to perform command decoding processing on the first pulse of the chip select signal and the command address signal based on the first clock signal to obtain the first command signal; the address decoding circuit is configured to perform row address decoding processing on the second pulse of the chip select signal and the command address signal based on the first command signal and the first clock signal to obtain the n second command signals and the n third command signals; and the logic processing circuit is configured to perform logic processing based on the n second command signals and the n third command signals to obtain the n segment activation signals. The n segments of each of the memory banks correspond to the n segment activation signals. Each of the segment activation signals is configured to indicate whether a segment corresponding to at least one of the m memory banks has been activated. In this way, if it can be determined based on the segment activation signal that a segment corresponding to each of some memory banks has been activated, it means that the segment corresponding to each of these memory banks has already been accessed. Then, the segment needs to be periodically refreshed in the refresh operation stage. Otherwise, if it can be determined based on the segment activation signal that a segment corresponding to each of some memory banks has not been activated, it means that the segment corresponding to each of these memory banks has not been accessed. Then, refresh masking may be performed for the segment in the refresh operation stage. In this way, integrity of data in the memory banks can be maintained, and power consumption can be further reduced, thereby achieving an objective of power saving.

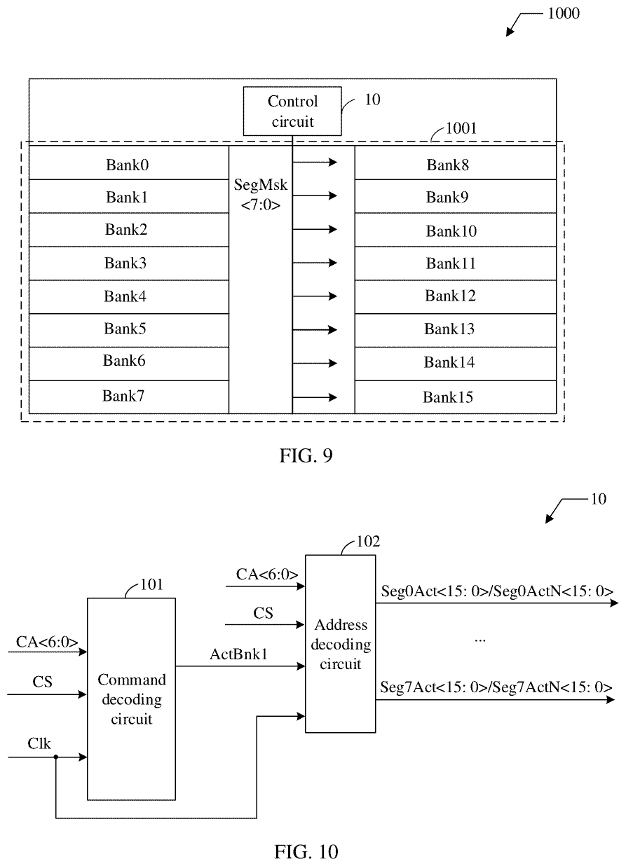

In another embodiment of the present disclosure, refer to FIG. 9, which is a schematic diagram of an architecture of a memory according to an embodiment of the present disclosure. As shown in FIG. 9, the memory 1000 may include a control circuit 10 and a memory array 1001. The memory array 1001 may include multiple memory banks, which are specifically Bank0, Bank1, Bank2, . . . , and Bank15. The control circuit 10 is configured to output target segment mask signals SegMsk<7:0>, and then send the target segment mask signals SegMsk<7:0> to each of the memory banks in the memory array 1001, to control a refresh operation for each of the memory banks. For example, Table 1 is utilized as an example. If both segment mask signals corresponding to the segment 2 and the segment 7 are 1, the refresh operation is masked for the segment 2 and the segment 7 in each of these memory banks.

Further, in this embodiment of the present disclosure, the control circuit 10 herein may be a power-saving refresh operation control circuit. Based on the descriptions of the foregoing embodiment, the control circuit 10 includes at least a logic processing circuit, a mode register, and an output circuit. The logic processing circuit is configured to output segment activation signals ActSegMsk<7:0>. The mode register is configured to output initial segment mask signals MRSegMsk<7:0>. The output circuit is configured to perform OR logic processing on the segment activation signals ActSegMsk<7:0> and the initial segment mask signals MRSegMsk<7:0> to finally generate the target segment mask signals SegMsk<7:0>. Then, the target segment mask signals SegMsk<7:0> may be sent to each of the memory banks in the memory array 1001.

In a specific embodiment, it is assumed that a value of m is 16, and a value of n is 8. Based on refinement and integration on the foregoing embodiments, FIG. 10 is a schematic diagram of a refined structure of a local part of the control circuit 10 according to an embodiment of the present disclosure. As shown in FIG. 10, a command decoding circuit 101 and an address decoding circuit 102 may be included herein. An input of the command decoding circuit 101 includes a command address signal CA<6:0>, a chip select signal CS, and a first clock signal Clk. An output of the command decoding circuit 101 is a first command signal ActBnk1. Herein, in the command decoding circuit 101, command decoding processing may be performed on a first pulse of the chip select signal CS and the command address signal CA<6:0> based on the first clock signal Clk to obtain the first command signal ActBnk1. The first command signal ActBnk1 is configured to indicate whether to perform an activation operation on the 16 memory banks in the memory array. An input of the address decoding circuit 102 may include the command address signal CA<6:0>, the chip select signal CS, the first command signal ActBnk1, and the first clock signal Clk. In the address decoding circuit 102, row address decoding processing is performed on a second pulse of the chip select signal CS and the command address signal CA<6:0> based on the first command signal ActBnk1 and the first clock signal Clk to output seven second command signals and seven third command signals. Each of the second command signals is configured to indicate whether to perform an activation operation on a specific segment in each of the 16 memory banks. The third command signals are inverted signals of the second command signals. Specifically, the second command signals are Seg0Act<15:0>, Seg1Act<15:0>, . . . , and Seg7Act<15:0>; and the third command signals are Seg0ActN<15:0>, Seg1ActN<15:0>, . . . , and Seg7ActN<15:0>. For example, Seg0Act<15:0> is utilized as an example. This signal indicates whether to perform an activation operation on a 0th segment in each of the 16 memory banks.

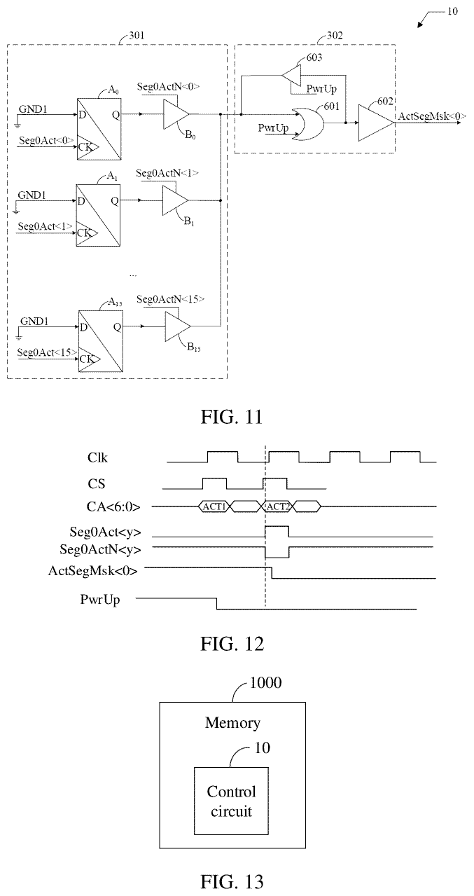

Further, the 0th segment is utilized as an example. For the logic processing circuit in the control circuit 10, refer to FIG. 11, which is a schematic diagram of a refined structure of a local part of the control circuit 10. As shown in FIG. 11, 16 logic sub-circuits 301 and a control sub-circuit 302 may be included herein. Each of the logic sub-circuits may include a latch module and a gated buffer module. The control sub-circuit 302 may include a first OR gate 601, a first buffer 602, and an mth gated buffer module 603. For a specific connection relationship, refer to FIG. 11.

In this embodiment of the present disclosure, for the power-saving control circuit 10 in a refresh operation mode, according to a technical standard formulated by the joint electron device engineering council (Joint Electron Device Engineering Council, JEDEC), segment (Segment) division may be performed based on different storage densities, and an access condition of each segment in each of the memory banks may be obtained through the command decoding circuit 101 and the address decoding circuit 102. SegxAct<15:0>/SegxActN<15:0> generated based on the command ActBnk1 is sent to the logic processing circuit in the control circuit 10 to generate the segment activation signals ActSegMsk<7:0>, where x=0, 1, 2, . . . , 7. When an xth segment activation signal ActSegMsk<x> is at a low level, it means that an xth segment in each of the 16 memory banks has been accessed, and a refresh operation cannot be masked when the refresh operation is performed. In this case, the refresh operation needs to be performed for the xth segment in each of the 16 memory banks. When an xth segment activation signal ActSegMsk<x> is at a high level, it means that an xth segment corresponding to at least one memory bank has not been accessed, and a refresh operation may be masked for the xth segment in at least one of the 16 memory banks when the refresh operation is performed. Therefore, an objective of power saving is achieved.

Based on the control circuit 10 in the foregoing embodiments, FIG. 12 is a schematic diagram of signal timing according to an embodiment of the present disclosure. As shown in FIG. 12, Clk is a first clock signal, CS is a chip select signal, CA<6:0> is a command address signal, and PwrUp is a power-up signal. Herein, a yth memory bank and an 0th segment are utilized as an example. Based on the first pulse of the chip select signal CS, command decoding processing may be performed on the first pulse of the chip select signal CS and the command address signal CA<6:0> based on the first clock signal Clk to obtain the first command signal ActBnk1, to indicate whether to perform an activation operation on the yth memory bank in the memory array. Then, based on the second pulse of the chip select signal CS, row address decoding processing may be performed on the second pulse of the chip select signal CS and the command address signal CA<6:0> based on the first command signal ActBnk1 and the first clock signal Clk to obtain a second command sub-signal Seg0Act<y> and a third command sub-signal Seg0ActN<y>. The second command sub-signal Seg0Act<y> is configured to indicate whether to perform an activation operation on the 0th segment in the yth memory bank, and the third command sub-signal Seg0ActN<y> is an inverted signal of the second command sub-signal Seg0Act<y>. In this way, after the second command sub-signals Seg0Act<15:0> and the third command sub-signals Seg0ActN<15:0> for all the memory banks are obtained, the logic processing is performed on the second command sub-signals Seg0Act<15:0> and the third command sub-signals Seg0ActN<15:0> through the latch module and the gated buffer module to obtain a first intermediate signal. Then, the logic processing is performed based on a power-up signal PwrUp and the first intermediate signal to obtain a segment activation signal ActSegMsk<0>. The segment activation signal is configured to indicate whether the 0th segment corresponding to the yth memory bank has been activated.

Specifically, in FIG. 12, if the second command sub-signal Seg0Act<y> changes from a low level to a high level, the third command sub-signal Seg0ActN<y> changes from a high level to a low level. In this case, the 0th segment of the yth memory bank has been accessed, that is, the activation operation is performed on the 0th segment of the yth memory bank. In this way, for the 0th segment in each of the 16 memory banks, if a high-level pulse occurs in the second command sub-signal Seg0Act<y>, it means that the 0th segment of the yth memory bank has been accessed. Although a first input terminal of the control sub-circuit 302 is connected to output terminals of the 16 gated buffer modules, an output of the latch module corresponding to the yth memory bank is at the low level when the high-level pulse occurs in the second command sub-signal Seg0Act<y>. In this case, the gated buffer module connected to the latch module can be turned on, and a low-level signal received at an input terminal of the gated buffer module is transmitted to an output terminal of the gated buffer module. However, a gated buffer module corresponding to a segment in another memory bank that has not been accessed is not turned on. Therefore, the first intermediate signal received through the first input terminal of the control sub-circuit 302 is at the low level. The OR logic processing is performed based on the power-up signal PwrUp and the first intermediate signal. Because both the power-up signal PwrUp and the first intermediate signal are at the low level, the finally obtained segment activation signal ActSegMsk<0> is at the low level. In addition, there is a slight delay time between the falling edge of the segment activation signal ActSegMsk<0> and the rising edge of the second command signal Seg0Act<y>, and the delay time is generated through logic components such as the latch module, the gated buffer module, the first OR gate, and the first buffer in the segment processing sub-circuit.

In this way, in this embodiment of the present disclosure, for the memory 1000 shown in FIG. 9, the segment activation signal ActSegMsk<7:0> is at the high level before power-up is completed and when power-up is just completed. After the ith segment in a corresponding memory bank has been accessed, a corresponding segment activation signal ActSegMsk<i> changes to the low level. Then, an OR logic operation is performed on the segment activation signals ActSegMsk<7:0> and initial segment mask signals MRSegMsk<7:0> set by the mode register to obtain final target segment mask signals SegMsk<7:0>. Then, the target segment mask signals SegMsk<7:0> are sent to the memory array 1001 for controlling of refresh operation masking, thereby reducing power consumption and achieving the objective of power saving.

In still another embodiment of the present disclosure, refer to FIG. 13, which is a schematic diagram of a compositional structure of a memory according to an embodiment of the present disclosure. As shown in FIG. 13, the memory 1000 includes at least the control circuit 10 described in the foregoing embodiments.

In some embodiments, the memory 1000 may include a DRAM chip. The DRAM chip may not only meet a memory specification such as DDR, DDR2, DDR3, DDR4, DDR5, and DDR6, but also meets a memory specification such as LPDDR, LPDDR2, LPDDR3, LPDDR4, LPDDR5, and LPDDR6. This is not specifically limited herein.

In this embodiment of the present disclosure, for the memory 1000, a segment activation signal is configured to indicate whether a segment corresponding to at least one of multiple memory banks has been activated. In this way, if it can be determined based on the segment activation signal that a segment corresponding to each of some memory banks has been activated, it means that the segment corresponding to each of these memory banks has already been accessed. Then, the segment needs to be periodically refreshed in a refresh operation stage. Otherwise, if it can be determined based on the segment activation signal that a segment corresponding to each of some memory banks has not been activated, it means that the segment corresponding to each of these memory banks has not been accessed. Then, refresh masking may be performed for the segment in a refresh operation stage. In this way, integrity of data in the memory banks can be maintained, and power consumption can be further reduced, thereby achieving an objective of power saving, and finally improving performance of the memory.

The foregoing embodiments are merely preferred embodiments of the present disclosure, and are not intended to limit the protection scope of the present disclosure.

It should be noted that in the present disclosure, the terms “include”, “comprise”, or any other variant thereof are intended to cover non-exclusive inclusion, so that a procedure, method, article, or apparatus that includes a series of elements includes not only those elements but also other elements that are not expressly listed, or further includes elements inherent to such a procedure, method, article, or apparatus. An element preceded by “includes a . . . ” does not, without more constraints, preclude the presence of additional identical elements in the process, method, article, or apparatus including the element.

The sequence numbers of the foregoing embodiments of the present disclosure are merely for the purpose of description, and are not intended to indicate priorities of the embodiments.

The methods disclosed in the several method embodiments provided in the present disclosure may be randomly combined when there is no conflict, to obtain new method embodiments.

The features disclosed in the several product embodiments provided in the present disclosure may be randomly combined when there is no conflict, to obtain new product embodiments.

The features disclosed in the several method or device embodiments provided in the present disclosure may be randomly combined when there is no conflict, to obtain new method embodiments or new device embodiments.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A control circuit, comprising a command decoding circuit, an address decoding circuit, and a logic processing circuit, the command decoding circuit being connected to the address decoding circuit, and the address decoding circuit being further connected to the logic processing circuit;
the command decoding circuit being configured to receive a command address signal, a chip select signal, and a first clock signal, and perform command decoding processing on a first pulse of the chip select signal and the command address signal based on the first clock signal to obtain a first command signal, the first command signal being configured to indicate whether to perform an activation operation on m memory banks in a memory array, wherein m is a positive integer;
the address decoding circuit being configured to receive the first command signal, the first clock signal, the chip select signal, and the command address signal, and perform row address decoding processing on a second pulse of the chip select signal and the command address signal based on the first command signal and the first clock signal to obtain n second command signals, each of the second command signals being configured to indicate whether to perform an activation operation on a specific segment in each of the m memory banks, wherein n is a positive integer; and
the logic processing circuit being configured to receive the n second command signals, and perform logic processing based on the n second command signals to obtain n segment activation signals, each of the segment activation signals being configured to indicate whether a segment corresponding to at least one of the m memory banks has been activated, wherein
the memory array comprises the m memory banks, each of the memory banks comprises n segments, and the n segments correspond to the n segment activation signals.

2. The control circuit according to claim 1, wherein the first command signal comprises m first command sub-signals, and the m first command sub-signals correspond to the m memory banks; and
if the first command sub-signals are in a first level state, it is determined to perform an activation operation on the memory banks corresponding to the first command sub-signals; or
if the first command sub-signals are in a second level state, it is determined to skip performing an activation operation on the memory banks corresponding to the first command sub-signals.

3. The control circuit according to claim 1, wherein
the address decoding circuit is further configured to perform row address decoding processing on the second pulse of the chip select signal and the command address signal based on the first command signal and the first clock signal to obtain n third command signals, wherein the second command signals and the third command signals are inversely related to each other; and
the logic processing circuit is configured to receive the n second command signals and the n third command signals, and perform logic processing based on the n second command signals and the n third command signals to obtain the n segment activation signals.

4. The control circuit according to claim 3, wherein the logic processing circuit comprises n segment processing sub-circuits; and
an ith segment processing sub-circuit is configured to receive an ith second command signal and an ith third command signal, and perform logic processing based on the ith second command signal and the ith third command signal to obtain an ith segment activation signal,
the ith segment activation signal being configured to indicate whether an ith segment corresponding to at least one of the m memory banks has been activated, wherein i is an integer greater than or equal to 0 and less than n.

5. The control circuit according to claim 4, wherein
each of the second command signals comprises m second command sub-signals;
each of the third command signals comprises m third command sub-signals; and
the second command sub-signals and the third command sub-signals are inversely related to each other, both a kth second command sub-signal in the second command signal and a kth third command sub-signal in the third command signal correspond to a kth memory bank, and k is an integer greater than or equal to 0 and less than m.

6. The control circuit according to claim 5, wherein the ith segment processing sub-circuit comprises m logic sub-circuits and a control sub-circuit;
a jth logic sub-circuit is configured to receive a ground signal, a jth second command sub-signal, and a jth third command sub-signal, an output terminal of the jth logic sub-circuit is configured to output a jth first intermediate signal, and j is an integer greater than or equal to 0 and less than m;
a first input terminal of the control sub-circuit is connected to output terminals of the m logic sub-circuits, a second input terminal of the control sub-circuit is configured to receive a power-up signal, and an output terminal of the control sub-circuit is configured to output the ith segment activation signal; and
the chip select signal is a signal representing that a target chip is selected, and the power-up signal represents that all power supplies of the target chip are started.

7. The control circuit according to claim 6, wherein the jth logic sub-circuit comprises a jth latch module and a jth gated buffer module, an output terminal of the jth latch module is connected to an input terminal of the jth gated buffer module, and a control terminal of the jth gated buffer module is configured to receive the jth third command sub-signal;
the jth latch module is configured to receive the ground signal and the jth second command sub-signal, and control a latch status of the jth latch module based on the jth second command sub-signal to generate a jth second intermediate signal; and
the jth gated buffer module is configured to receive the jth second intermediate signal and the jth third command sub-signal, and control a conduction status of the jth gated buffer module based on the jth third command sub-signal to generate the jth first intermediate signal.

8. The control circuit according to claim 7, wherein
the jth logic sub-circuit is configured to: when the jth second command sub-signal is in the first level state and the jth third command sub-signal is in the second level state, determine that the jth second intermediate signal is in the second level state and the jth gated buffer module is in an on state, so that the jth first intermediate signal is in the second level state.

9. The control circuit according to claim 7, wherein
the jth logic sub-circuit is configured to: when the jth second command sub-signal is in the second level state and the jth third command sub-signal is in the first level state, determine that the jth gated buffer module is in an off state, so that an output of the jth gated buffer module is in a high-impedance state.

10. The control circuit according to claim 7, wherein the control sub-circuit comprises a first OR gate, a first buffer, and an mth gated buffer module; and
a first input terminal of the first OR gate is separately connected to the output terminals of the m logic sub-circuits and an output terminal of the mth gated buffer module, a second input terminal of the first OR gate is configured to receive the power-up signal, an output terminal of the first OR gate is separately connected to an input terminal of the mth gated buffer module and an input terminal of the first buffer, a control terminal of the mth gated buffer module is configured to receive the power-up signal, and an output terminal of the first buffer is configured to output the ith segment activation signal.

11. The control circuit according to claim 1, further comprising a mode register and an output circuit,
the mode register being configured to output n initial segment mask signals, each of the initial segment mask signals being set by the mode register and being configured to indicate whether refresh masking is performed for the specific segment in each of the m memory banks; and
the output circuit being configured to receive the n segment activation signals and the n initial segment mask signals, and perform OR logic processing on the n segment activation signals and the n initial segment mask signals to generate n target segment mask signals, wherein
if an ith target segment mask signal is in the first level state, a refresh operation is masked for the ith segment corresponding to at least one of the m memory banks when the refresh operation is performed; or
if an ith target segment mask signal is in the second level state, a refresh operation is not masked for the ith segment corresponding to each of the m memory banks when the refresh operation is performed.

12. The control circuit according to claim 2, wherein the first level state is a high level, and the second level state is a low level.

13. The control circuit according to claim 11, wherein the output circuit comprises n second OR gates;
a first input terminal of a pth second OR gate is configured to receive a pth segment activation signal, a second input terminal of the pth second OR gate is configured to receive a pth initial segment mask signal, and an output terminal of the pth second OR gate is configured to output a pth target segment mask signal; and
p is an integer greater than or equal to 0 and less than n.

14. The control circuit according to claim 11, wherein the output circuit comprises n second OR gates and n second buffers, and an input terminal of a pth second buffer is connected to an output terminal of the pth second OR gate;
the pth second OR gate is configured to receive a pth segment activation signal and a pth initial segment mask signal, and perform an OR logic operation on the pth segment activation signal and the pth initial segment mask signal to obtain a pth intermediate segment mask signal;
the pth second buffer is configured to perform drive enhancement processing on the pth intermediate segment mask signal to obtain a pth target segment mask signal; and
p is an integer greater than 0 and less than or equal to n.

15. A memory, comprising at least the control circuit according to claim 1.
